(19) United States
(12) Patent Application Publication
(10) Pub. No.: US 2026/0096070 A1
(43) Pub. Date: Apr. 2, 2026

(54) HEAT DISSIPATION STRUCTURE ABLE TO IMPROVE HEAT DISSIPATION PERFORMANCE OF POWER COMPONENT AND ELECTRONIC LOAD DEVICE THEREOF

(71) Applicant: CHROMA ATE INC., Taoyuan City (TW)

(72) Inventors: CHING-WEN LIN, Taoyuan City (TW); CHIEN-HSING HUANG, Taoyuan City (TW); HSIAO-CHING CHIANG, Taoyuan City (TW)

(21) Appl. No.: 19/221,605

(22) Filed: May 29, 2025

(30) Foreign Application Priority Data
Sep. 27, 2024 (TW) 113137177

(51) Int. Cl. H05K 7/20

(52) U.S. Cl. CPC H05K 7/209

(57) ABSTRACT

A heat dissipation structure able to improve heat dissipation performance of a power component and an electronic load device thereof. The heat dissipation structure includes a first heat dissipation element and a first circuit module. The first heat dissipation element includes a first protrusion projecting from a first mounting side. The first circuit module includes a first substrate disposed on the first mounting side and a first power component disposed on the first substrate. The first substrate includes a first through hole for the first protrusion to extend therein, for the first protrusion to support a first polarity portion of the first power component. A first heat conduction path is formed between the first power component and the first heat dissipation element by the first protrusion.

### BACKGROUND OF THE INVENTION

### Field of the Invention

The present invention relates to a heat dissipation structure and an electrode load device using the heat dissipation structure, and more particularly to a heat dissipation structure adapted to improve heat dissipation performance of a power component and an electronic load device using the heat dissipation structure.

### Description of the Prior Art

A power component, for example, a power transistor, is applicable to process large-power conditions under different voltage and current combinations. For example, a metal-oxide-semiconductor field-effect transistor (MOSFET) is a power transistor that is frequently used. During large-power use, a power component causes a greater amount of heat energy. In order to maintain stable operations of a device, the arrangement of a heat dissipation structure of the power component is thus critical.

When a power component is used, a related conventional power device is restricted by the problem of a heat source caused by demands for large power, such that the power component needs to be mounted to a circuit board by using a dual in-line package (DIP) to meet power and heat dissipation requirements. However, the configuration above necessarily involves a time-consuming processing method of locking by screws to arrange the power component, and the overall configuration space is also limited due to such processing method.

By controlling an internal power component to conduct a hole channel, an electronic load device allows a current to pass through the power component under a voltage condition at that instant, hence causing a MOSFET to dissipate power, consuming electrical energy, and achieving simulation of a power environment. For development and manufacturing of power devices, an electronic load device is an indispensable test device. Therefore, to meet large-power utilization requirements and corresponding heat dissipation requirements, there is a need for a configuration able to increase a power transistor density and heat dissipation performance.

### SUMMARY OF THE INVENTION

A heat dissipation structure and a power load device using the heat dissipation structure disclosed in some embodiments enhance heat dissipation performance.

A heat dissipation structure and a power load device using the heat dissipation structure disclosed in some embodiments provide a power component with a better configuration to facilitate production and save a configuration space.

According to some embodiments, a heat dissipation structure able to improve heat dissipation performance of a power component includes a first heat dissipation element and a first circuit module. The first heat dissipation element includes a first protrusion projecting from a first mounting side. The first circuit module includes a first substrate disposed on the first mounting side and a first power component disposed on the first substrate. The first substrate includes a first through hole for the first protrusion to extend therein, for the first protrusion to support a first polarity portion of the first power component. A first heat conduction path is formed between the first power component and the first heat dissipation element by the first protrusion.

According to some embodiments, an electronic load device includes a first heat dissipation element, a first circuit module, a first connecting portion and a second connecting portion. The first heat dissipation element includes a first mounting side and a plurality of first protrusions projecting from the first mounting side. The first circuit module includes a first substrate disposed on the first mounting side, a plurality of first power components disposed on the first substrate, and a first conductive sheet disposed over the first substrate. The first substrate includes a plurality of first through holes for the corresponding first protrusions to extend therein. At least one of the first power components is supported at a first polarity portion by the corresponding first protrusion. A first heat conduction path is formed between each of the first power components and the first heat dissipation element by the corresponding first protrusion. The first connecting portion is coupled to an end of the first heat dissipation element. The second connecting portion is coupled to an end of the first conductive sheet.

According to some embodiments, the electronic load device may further include a second heat dissipation element, a second circuit module and a plurality of conductive columns. The second heat dissipation element may include a second mounting side and a plurality of second protrusions projecting from the second mounting side. The second circuit module may include a second substrate disposed on the second mounting side, a plurality of second power components disposed on the second substrate, and a second conductive sheet disposed over the second substrate. The second substrate includes a plurality of second through holes for the corresponding second protrusions to extend therein. At least one of the second power components is supported at a third polarity portion by the corresponding second protrusion. A second heat conduction path is formed between each of the second power components and the second heat dissipation element by the corresponding second protrusion. One end of each of the conductive columns may be connected to the first conductive sheet, the other end of each of the conductive columns may be connected to the second conductive sheet, and the second conductive sheet may be coupled to the first conductive sheet by these conductive columns. The first heat dissipation element may include a first fin side opposite to the first mounting side, and the second heat dissipation element may include a second fin side opposite to the second mounting side. The first heat dissipation element is connected to the second heat dissipation element, the second fin side faces the first fin side, and the third polarity portion of each of the second power components is coupled to the second heat dissipation element and the first connecting portion.

According to some embodiments, the first circuit module may include a first conductive sheet disposed over the first substrate, and the first conductive sheet may provide a downward pressure on a first side of the first power component, the first side being opposite to the first polarity portion.

According to some embodiments, the second conductive sheet may be configured to provide a downward pressure on a second side of each of the second power components, the second side being opposite to each of the third polarity portions.

According to some embodiments, the first circuit module may include a plurality of first pads disposed between and pressed against the first conductive sheet and the first side of each of the first power components corresponding thereto.

According to some embodiments, the second circuit module may further include a plurality of second pads disposed between and pressed against the second conductive sheet and the second side of each of the second power components corresponding thereto.

According to some embodiments, a second polarity portion of each of the first power components is soldered onto the first substrate and is coupled to the first conductive sheet and the second connecting portion.

According to some embodiments, a fourth polarity portion of each of the second power components is soldered onto the second substrate and is coupled to the second conductive sheet, and the fourth polarity portion of each of the second power components is coupled to the first conductive sheet and the second connecting portion via the second conductive sheet.

According to some embodiments, each of the first power components and each of the second power components may be soldered by means of surface mount technology onto the corresponding first substrate or second substrate.

Accordingly, the heat dissipation structure is able to improve heat dissipation performance, and thus can be used in power components having higher power and/or power components having higher arrangement densities. Moreover, the heat dissipation structure used in related power devices such as an electronic load device further provides an advantage of ease of manufacturing.

### BRIEF DESCRIPTION OF THE DRAWINGS

FIG. 1 is a perspective schematic diagram of a heat dissipation structure according to some embodiments;

FIG. 2 is a cross-sectional schematic diagram taken along line AA of FIG. 1;

FIG. 3 is an exploded perspective schematic diagram of FIG. 1;

FIG. 4 is an exploded perspective schematic diagram of a heat dissipation structure used in an electronic load device according to some other embodiments;

FIG. 5 is a cross-sectional schematic diagram of a heat dissipation structure used in an electronic load device according to some other embodiments; and

FIG. 6 is a cross-sectional schematic diagram of a heat dissipation structure used in an electronic load device according to yet some other embodiments.

### DETAILED DESCRIPTION OF THE EMBODIMENTS

Objectives, features, and advantages of the present disclosure are hereunder illustrated with specific embodiments, depicted with drawings, and described below.

In the disclosure, descriptive terms such as “a” or “one” are used to describe the unit, component, structure, device, module, portion, section or region, and are for illustration purposes and providing generic meaning to the scope of the present invention. Therefore, unless otherwise explicitly specified, such description should be understood as including one or at least one, and a singular number also includes a plural number.

In the disclosure, descriptive terms such as “include, comprise, have” or other similar terms are not for merely limiting the essential elements listed in the disclosure, but can include other elements that are not explicitly listed and are however usually inherent in the units, components, structures, devices, modules, portions, sections or regions.

In the disclosure, the terms similar to ordinals such as “first” or “second” described are for distinguishing or referring to associated identical or similar components or structures, and do not necessarily imply the orders of these components, structures, portions, sections or regions in a spatial aspect. It should be understood that, in some situations or configurations, the ordinal terms could be interchangeably used without affecting the implementation of the present invention.

In the disclosure, the term “coupled” as described herein may refer to two or more elements or features being in direct physical contact with each other, or being in indirect physical contact with each other. It may also refer to two or more elements or features interacting or operating with each other, or being electrically connected-either directly or indirectly-via electricity or electrical signals.

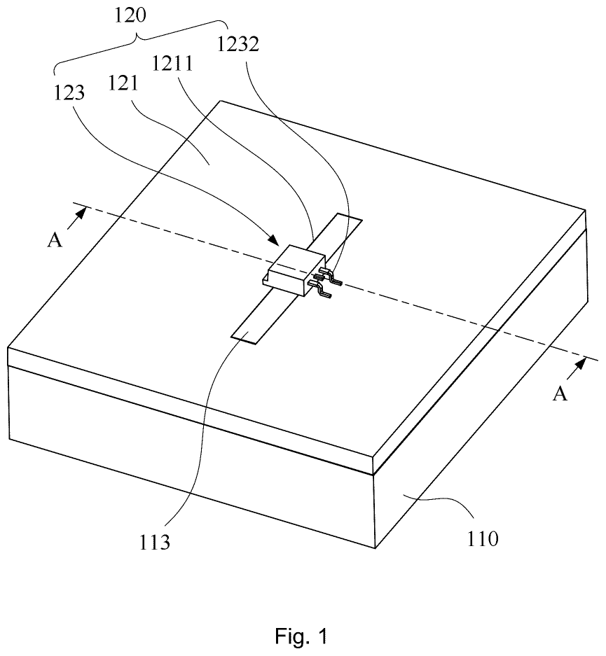

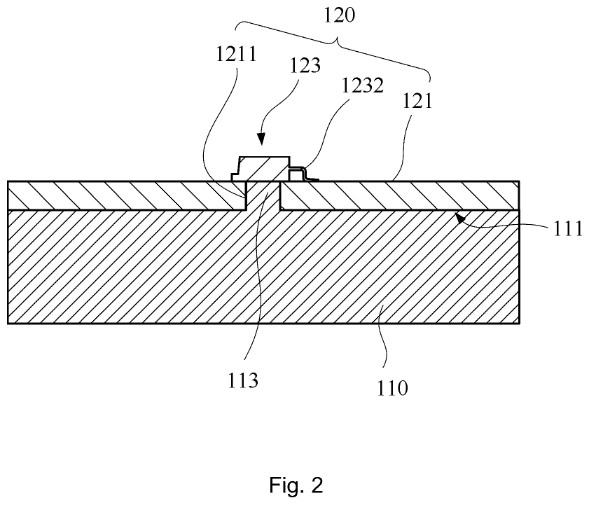

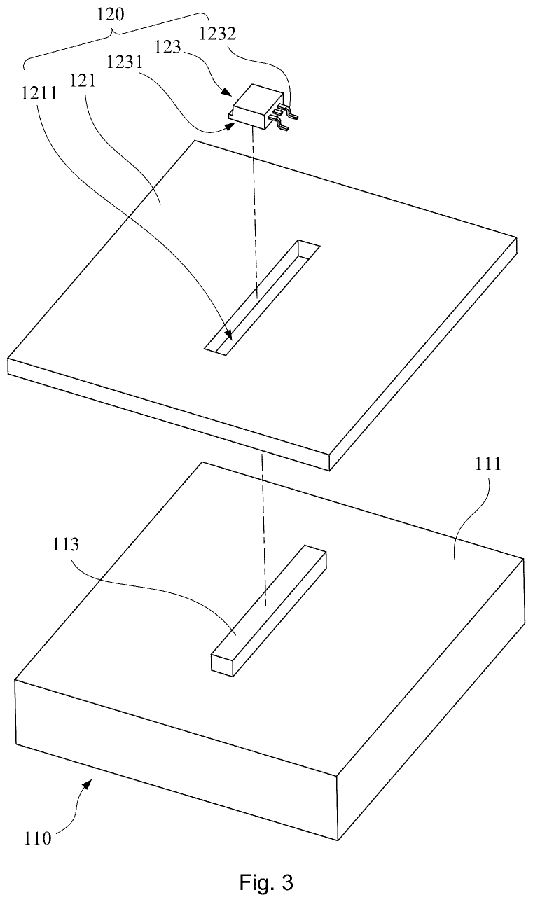

Referring to FIG. 1 to FIG. 3, FIG. 1 shows a perspective schematic diagram of a heat dissipation structure according to some embodiments. FIG. 2 shows a cross-sectional schematic diagram taken along line AA of FIG. 1. FIG. 3 shows an exploded perspective schematic diagram of FIG. 1.

The heat dissipation structure includes a first heat dissipation element 110 and a first circuit module 120. The first heat dissipation element 110 includes a first protrusion 113 projecting from a first mounting side 111. The first circuit module 120 includes a first substrate 121 and a first power component 123. The first power component 123 is used to be disposed on the first substrate 121 and may be coupled to a corresponding circuit of the first substrate 121. The first substrate 121 includes a first through hole 1211 penetrating a substrate body. The first substrate 121 is carried by the first heat dissipation element 110. During the carrying, the first protrusion 113 of the first heat dissipation element 110 may extend into the corresponding first through hole 1211. Moreover, the first protrusion 113 may be used to support a first polarity portion 1231 of the first power component 123.

The first protrusion 113 may be formed by extending from a body of the first heat dissipation element 110, or the first protrusion 113 may be an independent body and form a pattern of projecting from the first mounting side 111 by means of mounting to the body of the first heat dissipation element 110. The first mounting side 111 of the first heat dissipation element 110 may be used to carry the first circuit module 120. Another side opposite to the first mounting side 111 or adjacent to the first mounting side 111 may be disposed with a fin or configured to have a shape with a heat dissipation ability, or may coordinate with other cooling sources.

A support relationship between an upper surface of the first protrusion 113 and a lower surface (that is, the first polarity portion 1231) of the first power component 123 may include direct or indirect contact. For example, thermal paste may be additionally filled between the first protrusion 113 and the first polarity portion 1231 of the first power component 123 to increase a contact area and further improve heat conduction efficiency, achieving indirect or partial indirect contact (a part that cannot be in direct contact by filling of the thermal paste) between the first protrusion 113 and the first polarity portion 1231. In another aspect, a heat conducting pad or other heat conducting substances may also be used as a medium between the first protrusion 113 and the first polarity portion 1231 to achieve indirect contact. In yet another aspect, when the degrees of levelness of surfaces of the first protrusion 113 and the first polarity portion 1231 are to a certain extent, the upper surface of the first protrusion 113 may be in contact with the lower surface of the first power component 123 merely by direct contact.

With the first protrusion 113, a first heat conduction path is formed between the first power component 123 and the first heat dissipation element 110. In other words, heat or most heat generated during operation of the first power component 123 may be directly transferred to the first heat dissipation element 110 (the first protrusion 113 acts as a tentacle extending from the first heat dissipation element 110) via the first protrusion 113, hence achieving heat dissipation without transferring heat via the first substrate 121.

With the first protrusion 113 and the matching first through hole 1211 of the first substrate 121, the heat dissipation structure may be configured such that the first power component 123 is positioned lying on the first substrate 121, which facilitates spatial arrangement and reduces the overall footprint. Moreover, for a second polarity portion 1232 of the first power component 123, the first power component 123 may also be quickly disposed on the first substrate 121 by means of soldering or even by means of surface mount technology (SMT). With respect to the conventional time-consuming processing method of manually securing with screws, the approach above improves production yield rate and convenience; in other words, advantages of ease of manufacturing and improved heat dissipation performance are achieved. Accordingly, the configuration of such heat dissipation structure is suitable for a limited space within an electronic device, and at the same time provides outstanding heat dissipation performance as well as benefits for mass production.

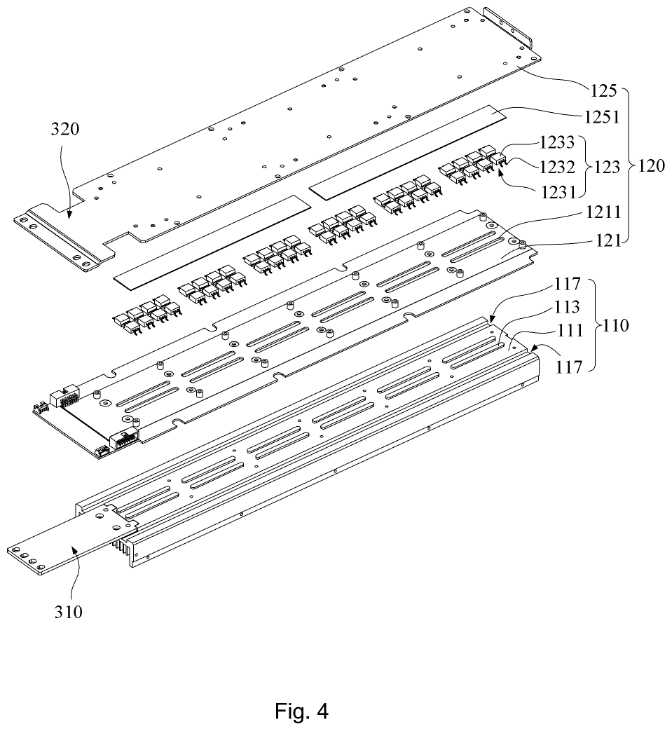

Refer to FIG. 4 showing an exploded perspective schematic diagram of a heat dissipation structure used in an electronic load device according to some other embodiments. The electronic load device includes a first heat dissipation element 110, a first circuit module 120, a first connecting portion 310 and a second connecting portion 320. The heat dissipation structure of the embodiment in FIG. 4 is configured on the basis of the embodiments in FIG. 1 to FIG. 3 and by varying the number of some of the elements. Each of the first connecting portion 310 and the second connecting portion 320 may be, for example, a conductive sheet, and may be implemented in an attached form (as exemplified by the first connecting portion 310 in FIG. 4) or an integral form (as exemplified by the second connecting portion 320 in FIG. 4).

The first heat dissipation element 110 includes a first mounting side 111 and a plurality of first protrusions 113. Each of the first protrusions 113 projects from a surface of the first mounting side 111.

The first circuit module 120 includes a first substrate 121, a plurality of first power components 123 and a first conductive sheet 125. The first substrate 121 is disposed on the first mounting side 111 of the first heat dissipation element 110, and the first substrate 121 includes a plurality of first through holes 1211 for the corresponding first protrusions 113 to extend therein. Each of the first power components 123 is disposed on the first substrate 121. The first conductive sheet 125 is disposed over the first substrate 121, and is for the first power component 123 to be clamped between the first conductive sheet 125 and the first substrate 121. Furthermore, a first polarity portion 1231 of each of the first power components 123 may be supported by the corresponding first protrusion 113, and the first conductive sheet 125 may provide a downward pressure on a first side 1233 of the first power component 123 opposite to the first polarity portion 1231, such that the first power component 123 may be securely clamped between the first conductive sheet 125 and the first substrate 121.

The first protrusions 113 may vary on the basis of the arrangement of the first power components 123 on the first substrate 121. As shown in FIG. 4, the first power components 123 are disposed into two strip-like rows on the first substrate 121, and the first protrusions 113 are also disposed into two rows each able to correspondingly support multiple first power components 123. Taking the example in FIG. 4 for instance, each of the first protrusions 113 correspondingly supports four first power components 123. Moreover, a first heat conduction path is formed between each of the first power components 123 and the first heat dissipation element 110 by the corresponding first protrusion 113. Taking the example in FIG. 4 for instance, a first heat conduction path is established between every four first power components 123 and the first heat dissipation element 110 by one corresponding first protrusion 113.

The first connecting portion 310 is coupled to an end of the first heat dissipation element 110. The second connecting portion 320 is coupled to an end of the first conductive sheet 125. In the example shown in FIG. 4, the electronic load device is configured with a large first conductive sheet 125 having an area equivalent to that of the first substrate 121, and the first conductive sheet 125 is mounted on the first substrate 121. With a circuit layout, a second polarity portion 1232 of each of the first power components 123 may be coupled to the first conductive sheet 125 and the second connecting portion 320. The first polarity portion 1231 of each of the first power components 123 is supported by the corresponding first protrusion 113 and thus is coupled to the first heat dissipation element 110 and the first connecting portion 310. The first connecting portion 310 may be configured to be coupled to a positive electrode of a power supply device to be tested, and the second connecting portion 320 is coupled to a negative electrode of the power supply device to be tested.

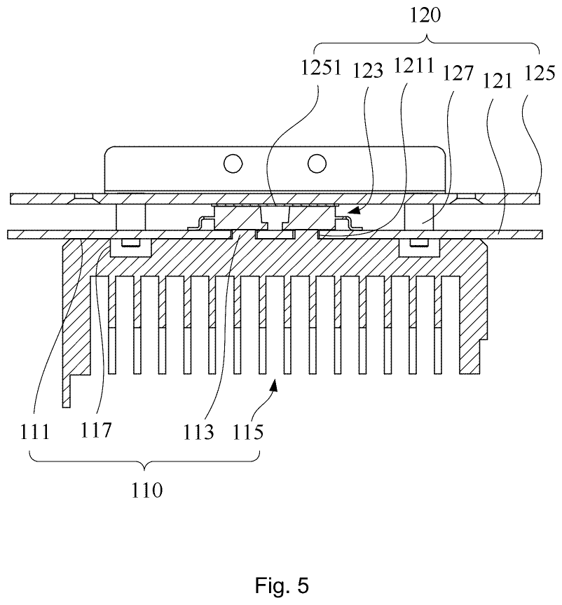

Next, refer to both FIG. 4 and FIG. 5. FIG. 5 shows a cross-sectional schematic diagram of a heat dissipation structure used in an electronic load device according to some other embodiments. The arrangement of FIG. 5 is similar to the example in FIG. 4, wherein the first conductive sheet 125, with a first support 127 mounted on the first substrate 121 and a bottom of the first support 127 projecting via a first groove 117 on the first heat dissipation element 110, may be further lockingly disposed with the first substrate 121. The first circuit module 120 further includes a plurality of first pads 1251 disposed between and pressed against the first conductive sheet 125 and a first side 1233 of each of the first power components 123 corresponding thereto. The first pads 1251 may be insulating soft pads or other pads, and may be used to allow the first conductive sheet 125 to more evenly apply a downward pressure upon each of the first power components 123.

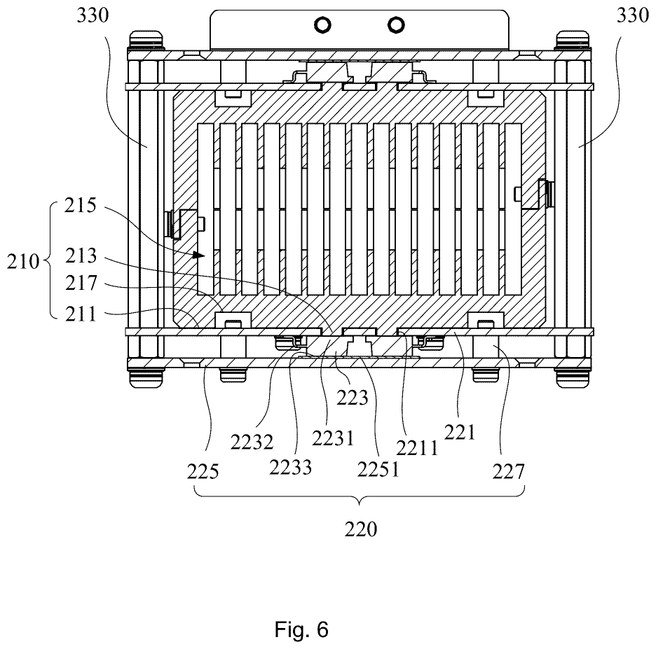

Next, refer to FIG. 6 showing a cross-sectional schematic diagram of a heat dissipation structure used in an electronic load device according to yet some other embodiments. Compared with the embodiment in FIG. 5, the example in FIG. 6 includes a second heat dissipation structure disposed below the first heat dissipation structure in FIG. 5, so as to form the configuration of an electronic load device having a greater number of power components as the example in FIG. 6. For the sake of simplicity of the drawing, the element numerals and symbols given in FIG. 5 are omitted from the same elements in FIG. 6.

The second heat dissipation structure shown in FIG. 6 includes a second heat dissipation element 210 and a second circuit module 220. The second heat dissipation element 210 includes a second mounting side 211 and a plurality of second protrusions 213 (similar to the plurality of first protrusions 113 shown in FIG. 4). Each of the second protrusions 213 projects from a surface of the second mounting side 211.

The second circuit module 220 includes a second substrate 221, a plurality of second power components 223 and a second conductive sheet 225. The second substrate 221 is disposed on the second mounting side 211 of the second heat dissipation element 210, and the second substrate 221 includes a plurality of second through holes 2211 for the corresponding second protrusions 213 to extend therein. Each of the second power components 223 is disposed on the second substrate 221. The second conductive sheet 225 is disposed over the second substrate 221, and is for the second power component 223 to be clamped between the second conductive sheet 225 and the second substrate 221. Furthermore, a third polarity portion 2231 of each of the second power components 223 may be supported by the corresponding second protrusion 213, and the second conductive sheet 225 may provide a downward pressure on a second side 2233 of the second power component 223 opposite to the third polarity portion 2231, such that the second power component 223 may be securely clamped between the second conductive sheet 225 and the second substrate 221.

Moreover, a second heat conduction path is formed between each of the second power components 223 and the second heat dissipation element 210 by the corresponding second protrusion 213. Similar to the example in FIG. 4, the second power components 223 in FIG. 6 may also be configured such that a second heat conduction path is established between every four second power components 223 and the second heat dissipation element 210 by one corresponding second protrusion 213.

Referring to both FIG. 5 and FIG. 6, the second heat dissipation element 210 includes a second fin side 215 opposite to the second mounting side 211, and the first heat dissipation element 110 includes a first fin side 115 opposite to the first mounting side 111. The first heat dissipation element 110 is connected to the second heat dissipation element 210 (for example, assembled together by means of matching structurally or in shape, or by other means), the second fin side 215 faces the first fin side 115, and the third polarity portion 2231 of each of the second power components 223 is coupled to the second heat dissipation element 210. On the basis that the second heat dissipation element 210 is connected to the first heat dissipation element 110, the third polarity portion 2231 of each of the second power components 223 may be coupled to the first connecting portion 310 (also with reference to FIG. 4) via the second heat dissipation element 210 and the first heat dissipation element 110, and be further configured to be coupled to a positive electrode of a power supply device to be tested.

In addition to the example in FIG. 5 having a configuration similar to that of the embodiment in FIG. 4, the example in FIG. 6 also has a configuration similar to that of the embodiment in FIG. 4 (FIG. 4 shows an example of the first groove 117). In the example in FIG. 6, the second conductive sheet 225, with a second support 227 mounted on the second conductive sheet 225 and a bottom of the second support 227 projecting via a second groove 217 on the second heat dissipation element 210, may be further lockingly disposed with the second substrate 221.

In another aspect, a plurality of conductive columns 330 are further included between the first heat dissipation structure and the second heat dissipation structure. One end of each of the conductive columns 330 is connected to the first conductive sheet 125, the other end of each of the conductive columns 330 is connected to the second conductive sheet 225. With these conductive columns 330, it can be further ensured that the first conductive sheet 125 and the second conductive sheet 225 provide downward pressures on the corresponding power components, wherein each of the second pads 2251 is disposed between and pressed against the second conductive sheet 225 and the second side 2233 of each of the second power components 223 corresponding thereto. Moreover, on the basis that each of the power components is supported by the corresponding first protrusion 113 or second protrusion 213, each of the power components can be securely fixed in the heat dissipation structure without involving any screws. In addition, with such structure, for both of the second polarity portion 1232 of the first power component 123 and a fourth polarity portion 2232 of the second power component 223, each of the power components can be quickly disposed on the corresponding substrate by means of soldering or by means of surface mount technology (SMT). With respect to the conventional time-consuming processing method that additionally requires manual locking of screws, the approach above improves production yield rate and convenience; in other words, advantages of ease of manufacturing and enhanced heat dissipation performance are achieved.

In conclusion, each of the power components may be configured via the various heat dissipation structures in the embodiments, and a heat conduction path can be directly established at an electrode portion at the bottom of each of the power components, hence improving heat dissipation efficiency and offering ease of manufacturing, further enabling the electronic load device or other electronic devices using power components to be suitable for power components having higher power and/or more power components.

The present disclosure is illustrated by various aspects and embodiments. However, persons skilled in the art understand that the various aspects and embodiments are illustrative rather than restrictive of the scope of the present disclosure. After perusing this specification, persons skilled in the art may come up with other aspects and embodiments without departing from the scope of the present disclosure. All equivalent variations and replacements of the aspects and the embodiments must fall within the scope of the present disclosure. Therefore, the scope of the protection of rights of the present disclosure shall be defined by the appended claims.

What is claimed is:

1. A heat dissipation structure able to improve heat dissipation performance of a power component, comprising:
a first heat dissipation element, comprising a first protrusion projecting from a first mounting side; and
a first circuit module, comprising a first substrate disposed on the first mounting side and a first power component disposed on the first substrate, wherein the first substrate comprises a first through hole allowing the first protrusion to extend therein, for the first protrusion to support a first polarity portion of the first power component, and a first heat conduction path is formed between the first power component and the first heat dissipation element by the first protrusion.

2. The heat dissipation structure according to claim 1, wherein the first circuit module further comprises a first conductive sheet disposed over the first substrate, and the first conductive sheet provides a downward pressure on a first side of the first power component, the first side being opposite to the first polarity portion.

3. The heat dissipation structure according to claim 2, wherein the first circuit module further comprises a first pad disposed between and pressed against the first conductive sheet and the first side of the first power component.

4. The heat dissipation structure according to claim 1, wherein a second polarity portion of the first power component is soldered onto the first substrate.

5. An electronic load device, comprising:
a first heat dissipation element, comprising a first mounting side and a plurality of first protrusions projecting from the first mounting side;
a first circuit module, comprising a first substrate disposed on the first mounting side, a plurality of first power components disposed on the first substrate and a first conductive sheet disposed over the first substrate, wherein the first substrate comprises a plurality of first through holes for the corresponding first protrusions to extend therein, at least one of the first power components is supported at the first polarity portion by the corresponding first protrusion, and a first heat conduction path is formed between each of the first power components and the first heat dissipation element by the corresponding first protrusion;
a first connecting portion, coupled to an end of the first heat dissipation element; and
a second connecting portion, coupled to an end of the first conductive sheet.

6. The electronic load device according to claim 5, wherein the first conductive sheet is configured to provide a downward pressure on a first side of the first power components, the first side being opposite to each of the first polarity portions.

7. The electronic load device according to claim 6, wherein the first circuit module further comprises a plurality of first pads disposed between and pressed against the first conductive sheet and the first side of each of the first power components corresponding thereto.

8. The electronic load device according to claim 7, wherein a second polarity portion of each of the first power components is soldered onto the first substrate and is coupled to the first conductive sheet and the second connecting portion.

9. The electronic load device according to claim 5, further comprising:
a second heat dissipation element, comprising a second mounting side and a plurality of second protrusions projecting from the second mounting side;
a second circuit module, comprising a second substrate disposed on the second mounting side, a plurality of second power components disposed on the second substrate and a second conductive sheet disposed over the second substrate, wherein the second substrate comprises a plurality of second through holes for the corresponding second protrusions to extend therein, at least one of the second power components is supported at a third polarity portion by the corresponding second protrusion, and a second heat conduction path is formed between each of the second power components and the second heat dissipation element by the corresponding second protrusion; and
a plurality of conductive columns, wherein one end of each of the conductive columns is connected to the first conductive sheet, one other end of each of the conductive columns is connected to the second conductive sheet, and the second conductive sheet is coupled to the first conductive sheet by the conductive columns,
wherein the first heat dissipation element comprises a first fin side opposite to the first mounting side, the second heat dissipation element comprises a second fin side opposite to the second mounting side, the first heat dissipation element is connected to the second heat dissipation element, the second fin side faces the first fin side, and the third polarity portion of each of the second power components is coupled to the second heat dissipation element and the first connecting portion.

10. The electronic load device according to claim 9, wherein the second conductive sheet is configured to provide a downward pressure on a second side of the second power components, the second side being opposite to each of the third polarity portions.

11. The electronic load device according to claim 10, wherein the second circuit module further comprises a plurality of second pads disposed between and pressed against the second conductive sheet and the second side of each of the second power components corresponding thereto.

12. The electronic load device according to claim 11, wherein a fourth polarity portion of each of the second power components is soldered onto the second substrate and is coupled to the second conductive sheet, and the fourth polarity portion of each of the second power components is coupled to the first conductive sheet and the second connecting portion via the second conductive sheet.

13. The electronic load device according to claim 12, wherein each of the first power components and each of the second power components are soldered by means of surface mount technology onto the corresponding first substrate or second substrate.
